(19) United States
(12) Patent Application Publication
(10) Pub. No.: US 2012/0306005 A1
(43) Pub. Date: Dec. 6, 2012

(54) Trough channel transistor and methods for making the same

(76) Inventors: Kimihiro Satoh, Beaverton, OR (US); Jing Zhang, Los Altos, CA (US); Yiming Huai, Pleasanton, CA (US)

(21) Appl. No.: 13/136,051

(22) Filed: Jul. 21, 2011

Related U.S. Application Data
(60) Provisional application No. 61/520,119, filed on Jun. 4, 2011.

(51) Int. Cl. H01L 29/78; H01L 21/336

(52) U.S. Cl. 257/330; 438/270; 257/E29.262; 257/E21.41

(57) ABSTRACT

The present invention relates to transistor devices having a trough channel structure through which electrical current flows and methods for making the same. A transistor device having a semiconductor trough structure comprises a semiconductor substrate of a first conductivity type having a top surface; a semiconductor trough protruded from the top surface of the substrate along a first direction and having two top surfaces, two outer lateral surfaces, and an inner surface; a layer of isolation insulator disposed on the substrate and abutting the outer lateral surfaces of the semiconductor trough; a gate dielectric layer lining the inner surface and the top surfaces of the semiconductor trough; and a gate electrode disposed on top of the isolation insulator and extending over and filling the semiconductor trough with the gate dielectric layer interposed therebetween. The gate electrode extends along a second direction not parallel to the first direction provided in the semiconductor trough. Regions of the semiconductor trough not directly beneath the gate electrode have a second conductivity type opposite to the first conductivity type provided in the substrate.

### RELATED APPLICATIONS

The present application is a continuation-in-part application of U.S. provisional patent application Ser. No. 61/520,119, filed Jun. 4, 2011, for TROUGH CHANNEL TRANSISTOR AND METHODS FOR MAKING THE SAME, by Kimihiro SATOH, included by reference herein and for which benefit of the priority date is hereby claimed.

### FIELD OF THE INVENTION

The present invention relates to transistor devices having a trough channel structure through which electrical current flows and methods for making the same.

### BACKGROUND OF THE INVENTION

Field-Effect Transistors (FETs), particularly Metal-Oxide-Semiconductor Field-Effect Transistors (MOSFETs), are the fundamental building block of integrated circuits and are ubiquitous in modern electronic devices. In a MOSFET device, when a voltage is applied to a gate electrode, charge carriers move between a source and a drain region via a conductive channel, which is formed by an electric field generated by the gate voltage through a thin layer of dielectric material interposed in between the gate electrode and the channel. The channel can be of p-type or n-type conductivity, depending on the fabrication method.

For the past half century the number of transistors on integrated circuits has been doubling every two years, following a trend commonly known as Moore's Law. Such a rapid increase in transistors is mainly accomplished by the miniaturization thereof. However, several difficulties can arise when scaling the transistor size, particularly the channel length, to sizes of a few tens of nanometers. As the channel length is reduced, there is a propensity for the formation of parasitic conduction paths between the source and the drain, thereby causing punch through current leakages. Another obstacle encountered in shrinking of transistors is reduced current drivability caused by the reduced width of the current-carrying channel. This can be a significant issue for newly emerged resistive memory devices which require higher current to switch their memory state.

To mitigate the above mentioned problems associated with the miniaturization of conventional transistors, a three dimensional MOSFET having a conductive channel region wrapped around a “fin” shaped silicon has been disclosed, for instance, in U.S. Pat. No. 7,948,037B2 issued to Chen et alia. FIG. 1 is a three dimensional view of such a FinFET device, which includes a substrate 101 comprising a lower substrate base layer 103 and an insulator base layer 105 disposed thereabove, a silicon fin 107 disposed on the insulator base layer 105, and a gate electrode 109 disposed on the insulator base layer 105 and wrapped around the silicon fin 107 with a thin gate dielectric layer 111 interposed therebetween. When an appropriate voltage is applied to the gate electrode 109, a conductive channel through which current flows is formed on the surface region of the fin 107 wrapped by the gate dielectric layer 111. Compared with the conventional planar MOSFET, the FinFET device illustrated in FIG. 1 has higher the current drivability because of the wrap-around channel design thereof.

A problem, however, associated with the FinFET device described above is that the active region of the device is formed on the insulator base layer 105, thereby making the substrate biasing of the FinFET device difficult.

Another problem associated with the FinFET device described above is that the need for insulator base layer 105 necessitates the use of expensive substrates such as Silicon-On-Insulator (SOI), thereby making the FinFET device more costly to fabricate.

### SUMMARY OF THE INVENTION

The present invention overcomes the current drivability and punch through current leakage issues associated with the conventional, planar MOSFET as well as fabrication cost and substrate biasing issues associated with the FinFET by using a novel trough structure through which current flows.

Accordingly, an object of the present invention is to provide a novel transistor device having a semiconductor trough structure through which current flows to mitigate the substrate biasing issue and fabrication cost associated with the prior art FinFET device.

Another object of the present invention is to provide methods for making the novel transistor device having a semiconductor trough structure.

Therefore, according to one aspect of the present invention, a transistor device having a semiconductor trough structure comprises a semiconductor substrate of a first conductivity type having a top surface; a semiconductor trough protruded from the top surface of the substrate along a first direction and having two top surfaces, two outer lateral surfaces, and an inner surface; a layer of isolation insulator disposed on the substrate and abutting the outer lateral surfaces of the semiconductor trough; a gate dielectric layer lining the inner surface and the top surfaces of the semiconductor trough; and a gate electrode disposed on top of the isolation insulator and extending over and filling the semiconductor trough with the gate dielectric layer interposed therebetween. The gate electrode extends along a second direction not parallel to the first direction provided in the semiconductor trough. Regions of the semiconductor trough not directly beneath the gate electrode have a second conductivity type opposite to the first conductivity type provided in the substrate.

According to another aspect of the present invention, a method for fabricating a trough channel transistor device having a semiconductor trough structure comprises the steps of providing a semiconductor substrate having a first type of conductivity; forming a mesa feature having a first hardmask thereover on the substrate; forming an isolation insulator layer, having substantially same height as the mesa feature with the first hardmask thereover, on top of the substrate and adjacent to the mesa feature; removing the first hardmask on the mesa feature to form a notch between the top surfaces of the mesa feature and the isolation insulator layer; forming a second hardmask aligned to the notch on the mesa feature; forming a trough structure by selectively etching the mesa feature with the second hardmask thereover; depositing a gate dielectric layer over the top and inner surfaces of the trough structure; forming a gate electrode filling the trough structure with the gate dielectric layer interposed therebetween; and implanting the trough structure with a dopant of a second type of conductivity, opposite to the first type provided by the substrate, using the gate electrode as a mask to define source and drain regions.

The objects, features, aspects, and advantages of the present invention are readily apparent from the following detailed description of the preferred embodiments for carrying out the invention when taken in connection with the accompanying drawings.

### BRIEF DESCRIPTION OF THE DRAWINGS

FIG. 1 is a perspective view illustrating a prior art FinFET device;

FIG. 2 is a perspective view of an embodiment of the present invention as applied to a n-type conductivity MOSFET device having a trough structure through which current flows;

FIG. 3 is another perspective view of the embodiment as applied to a n-type conductivity MOSFET device with the isolation insulator and the gate dielectric layer hidden to illustrate the structure of the semiconductor trough therebeneath;

FIG. 4 is a perspective view illustrating the operation of a n-type MOSFET device having a trough channel structure according to an embodiment of the present invention;

FIG. 5 is a perspective view of another embodiment of the present invention as applied to a p-type conductivity MOSFET device having a trough channel structure through which current flows; and

FIGS. 6-14 are perspective views illustrating various stages in formation of a MOSFET device according to embodiments of the present invention.

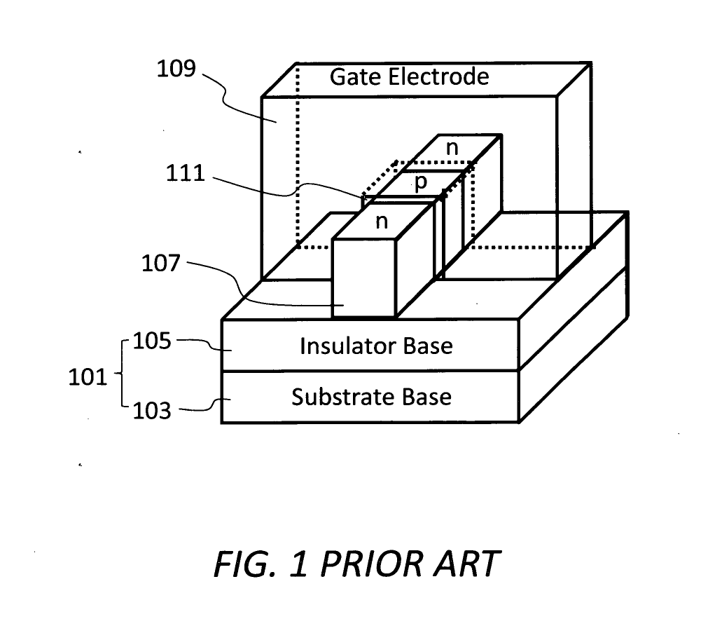

For purposes of clarity and brevity, like elements and components will bear the same designations and numbering throughout the Figures.

### DETAILED DESCRIPTION OF THE INVENTION

The present invention overcomes the current drivability and punch through current leakage issues associated with the conventional, planar MOSFET as well as the fabrication cost and substrate biasing issues associated with the FinFET by using a novel trough structure through which current flows.

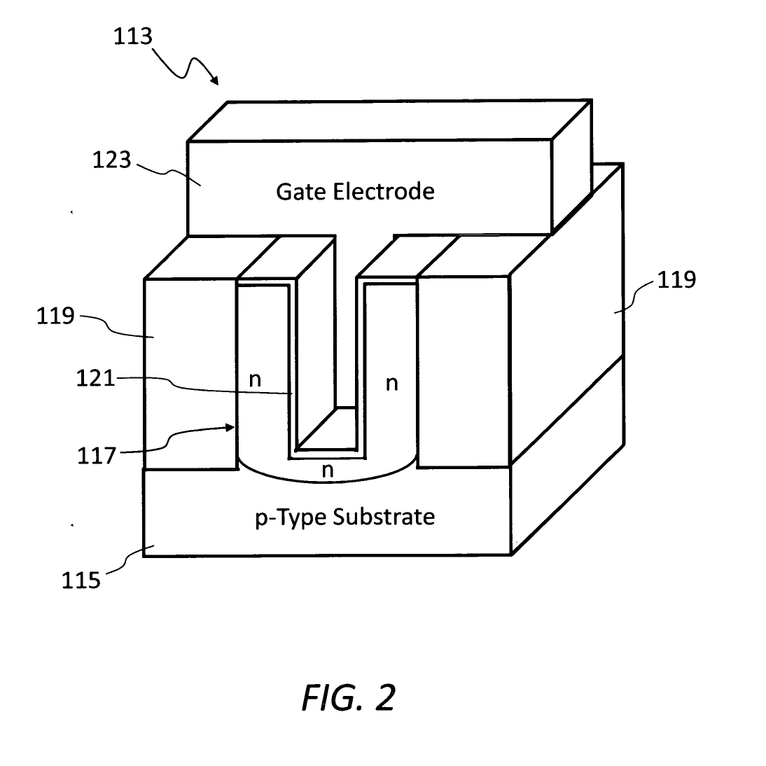

An embodiment of the present invention as applied to a n-type conductivity MOSFET device having a trough structure through which current flows will now be described with reference to FIG. 2. The illustrated device 113 comprises a semiconductor substrate 115 of the p-type conductivity having a top surface; a semiconductor trough 117 protruded from the top surface of the substrate 115 along a first direction and having two top surfaces, two outer lateral surfaces, and an inner surface; a layer of isolation insulator 119 disposed on the substrate 115 and abutting the outer lateral surfaces of the trough 117; a gate dielectric layer 121 lining the inner surface and the top surfaces of the trough 117; a gate electrode 123 disposed on top of the isolation insulator 119 and extending over and filling the semiconductor trough 117 with the gate dielectric layer 121 interposed therebetween. The gate electrode 123 extends along a second direction not parallel to the first direction provided in the semiconductor trough 117. Regions of the semiconductor trough not directly beneath the gate electrode have a second conductivity type opposite to the first conductivity type provided in the substrate.

The substrate 115 can be any semiconductor substrate known in the art, such as silicon (Si), silicon germanium (SiGe), silicon carbide (SiC), SiCGe, II-VI compounds, III-V compounds, or semiconducting epitaxial layers over such substrates. According to one embodiment of the present invention, the substrate 115 is a p-type silicon to provide a base for the formation of a n-type MOSFET device.

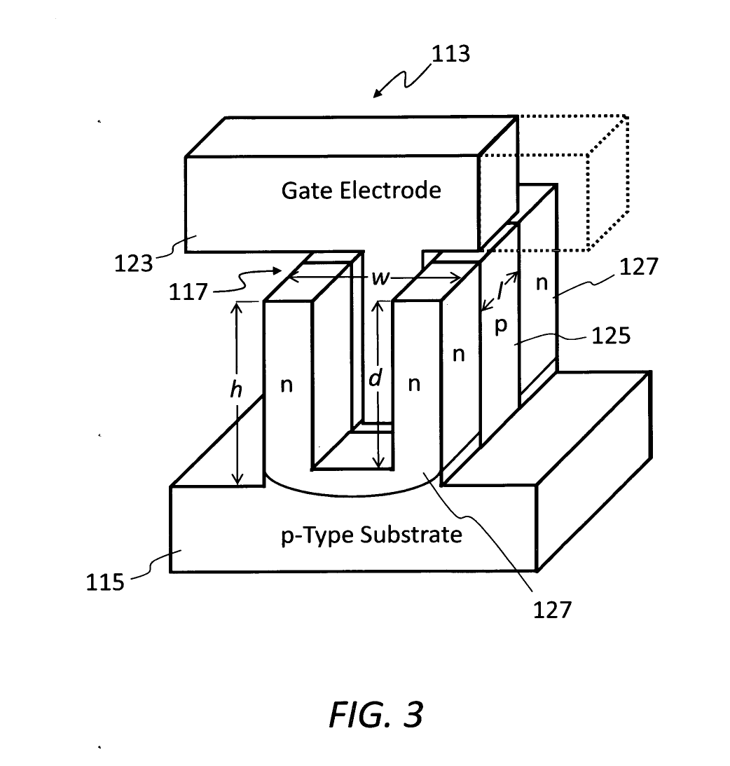

FIG. 3 is another view of the present device 113 shown in FIG. 2 with the isolation insulator 119 and the gate dielectric layer 121 hidden to illustrate the structure of the semiconductor trough 117 therebeneath. In the drawing numerals 115 to 123 denote the same components or substances as those shown in FIG. 2. Referring now to FIG. 3, the semiconductor trough 117 is formed on top of the substrate 115 by etching thereof. As such, the trough 117 is made of the same semiconductor material as the substrate 115. The semiconductor trough 117 has a width of w, depth of d, and overall height of h while extending along its axis. The trough depth is preferably shallower than the trough height. The semiconductor trough 117 includes regions of p-type and n-type conductivity along its axis of extension. For the present embodiment as applied to a n-type MOSFET, the p-type region of the trough 125 is beneath the gate electrode 123 and has the same type of conductivity as the substrate 115. The n-type regions 127, which bound the p-type region 125 along the axis of extension, are formed at the two ends of the trough 117 divided by the gate electrode 113 and respectively define source and drain regions. The n-type conductivity of the source and drain regions can be formed by doping with any suitable dopant such as phosphorous, arsenic, or antimony. When an appropriate voltage is applied to the gate electrode 123, the top and inner surfaces of the p-type region 125 adjacent to the gate dielectric (not shown) become a conductive path, or channel, through which current flows from the source to the drain. Accordingly, the effective width of this trough channel would be 2d+w and the channel length of l is defined by the width of the gate electrode 123. The trough cross section profile perpendicular to the extension axis thereof, as defined by the inner surface of the trough, is not limited to rectangular shapes but can also be triangular, trapezoidal, semi-circular, or semi-elliptical.

With continuing reference to FIG. 2, the function of the isolation insulator 119 is to electrically isolate the transistor device 113 from adjacent devices and to provide a generally planar, electrically insulating surface upon which the gate electrode 123 is formed. The isolation insulator 119 may comprise any dielectric material, such as but not limited to silicon oxide (SiOₓ), silicon nitride (SiNₓ), or silicon oxynitride (SiOₓN_{y}). The isolation insulator 119 may be formed by first depositing a layer of insulator film using any suitable thin film deposition method, such as Physical Vapor Deposition (PVD), Chemical Vapor Deposition (CVD), or Atomic Layer Deposition (ALD), and followed by planarizing the deposited film using Chemical Mechanical Polishing (CMP) or Ion Milling. The top surfaces of the isolation insulator 119, the height of which can be adjusted by the planarization process, are generally flush with the top surfaces of the semiconductor trough 117.

The gate dielectric layer 121 functions like an insulator medium of a capacitor device. When a voltage is applied to the gate electrode 123, an electric field is induced across the gate dielectric layer 121 to modulate the conductance of the trough channel on the opposite side. The gate dielectric layer 121 lining the top and inner surfaces of the semiconductor trough 117 preferably has a thickness of between 0.5-5 nm and may comprise any material with sufficiently high dielectric constant, including but not limited to SiOₓ, SiOₓN_{y}, hafnium oxide (HfOₓ), hafnium oxynitride (HfOₓN_{y}), hafnium silicate (HfSiOₓ), HfSiOₓN_{y}, zirconium oxide (ZrOₓ), zirconium oxynitride (ZrOₓN_{y}), zirconium silicate (ZrSiOₓ), ZrSiOₓN_{y}, aluminum oxide (AlOₓ), or combinations thereof. The gate dielectric layer 121 may be formed by thermal oxidation of the top and inner surfaces of the semiconductor trough 117 or by any suitable thin film deposition method, such as CVD or ALD. In some embodiments where the substrate 115 and the trough 117 are silicon, the gate dielectric layer 121 is preferably SiOₓ formed by thermal oxidation of the top and inner surfaces of the trough 117. In another embodiment, the gate dielectric layer 121 is formed of a compound comprising hafnium and oxygen, such as HfOₓ or HfSiOₓ.

The gate electrode 123 is formed on top of the isolation insulator 119 and fills the semiconductor trough 117 with the gate dielectric layer 121 interposed therebetween while extending along a second direction not parallel to the first direction provided in the semiconductor trough 117. The gate electrode 123 supplies voltage required to modulate the conductance of the trough channel through which current flows from the source to drain. The gate electrode 123 may comprise one or more layers of any suitable conductive material, such as doped polysilicon, tungsten silicide (WSiₓ), titanium silicide (TiSiₓ), cobalt silicide (CoSiₓ), nickel silicide (NiSiₓ), tantalum nitride (TaNₓ), titanium nitride (TiNₓ), tantalum (Ta), tungsten (W), or combinations thereof. The gate electrode 123 may be formed by first depositing one or more layers of conductors using thin film deposition methods such as Physical Vapor Deposition (PVD), Chemical Vapor Deposition (CVD), and Atomic Layer Deposition (ALD), and followed by photo lithography and Reactive Ion Etching (RIE) to define the gate electrode width, which also determines the channel length. In an embodiment, the gate electrode 123 comprises doped polysilicon. In another embodiment, the gate electrode 123 comprises at least one layer formed of TiNₓ.

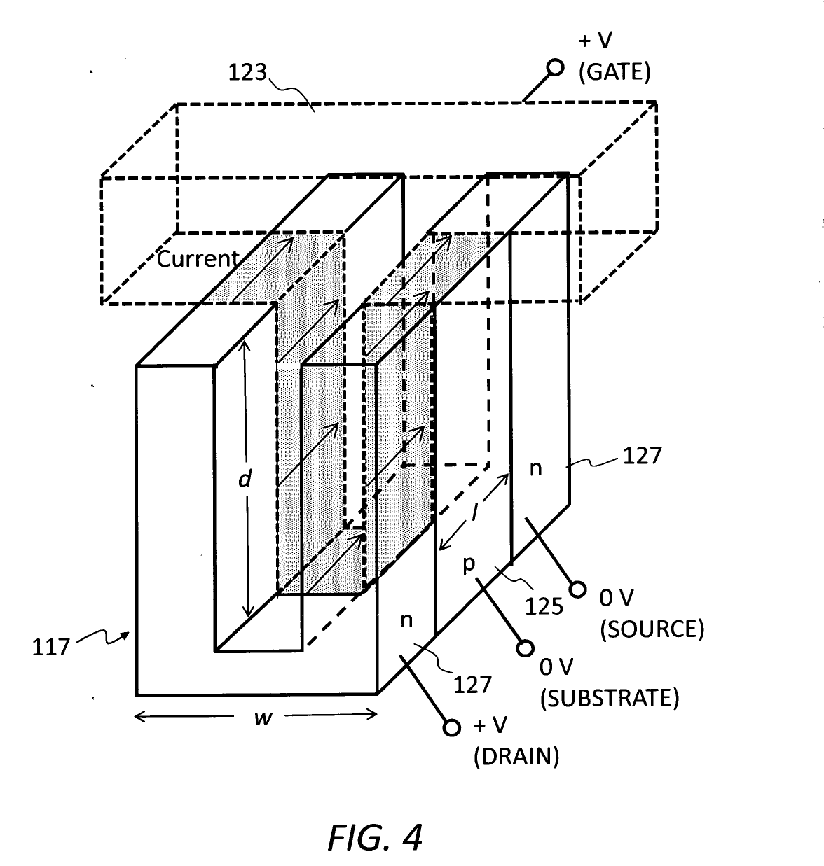

Operation of the n-type trough channel transistor device 113 will now be described with reference to FIG. 4. In the drawing numerals 117 to 123 denote the same components as those shown in FIG. 3. Referring now to FIG. 4, which shows the n-type regions 127 of the trough structure 117 respectively connect to the source and drain terminals. The p-type region 125 beneath the gate electrode 123 has the same potential as the substrate (not shown) and is normally grounded. The source terminal may be grounded by connecting to the substrate lead. A positive voltage with respect to the source is applied to the drain terminal. When a sufficient positive voltage is applied to the gate electrode 123 with respect to the source terminal, free holes near the gate dielectric layer in the p-region 125 are repelled away and electrons are then induced by the positive charge of the gate, thereby forming an inversion layer or n-channel as depicted by the shaded area, through which electrons can flow from the source to drain. As the gate voltage becomes increasingly positive, the electron concentration increases in the n-channel formed in the p-region 125, thereby allowing a higher current to flow from the drain to source. Compared with a conventional planar MOSFET having a channel width of w, a trough channel transistor with an equivalent footprint or device density would have an effective channel width of 2d+w as shown by the shaded area. Accordingly, the effective channel width and hence the currently drivability advantageously increase with increasing trough depth, d. Since the side walls of the trough 117 are relatively thin, free holes in the p-region 125 beneath the gate electrode 123 can be fully depleted with a low gate voltage, thereby allowing low power operation of the device.

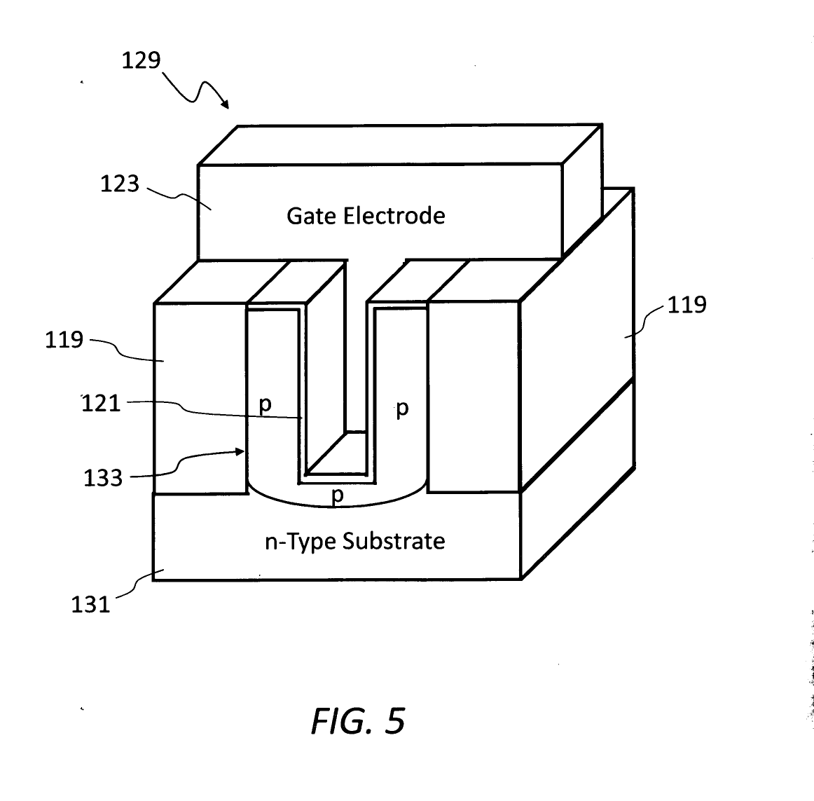

Another embodiment of the present invention as applied to a p-type trough channel transistor will be described with reference to FIG. 5. In the drawing numerals 119 to 123 denote the same components as those shown in FIG. 2. Referring now to FIG. 5, the p-type trough channel transistor 129 is different from the n-type trough channel transistor 113 shown in FIG. 2 in that the semiconductor substrate 131 and the region of the semiconductor trough 133 directly beneath the gate electrode 123 have a n-type conductivity, while the regions of the semiconductor trough separated by the n-type region have a p-type conductivity and respectively form source and drain regions. The operation of the p-type trough channel transistor device 129 is similar to that of the n-type trough channel transistor 113 described above except that a negative voltage is applied to the gate electrode 123 to form a p-type conductive trough channel through which current flows from source to drain as would be understood by a person of skill in the art.

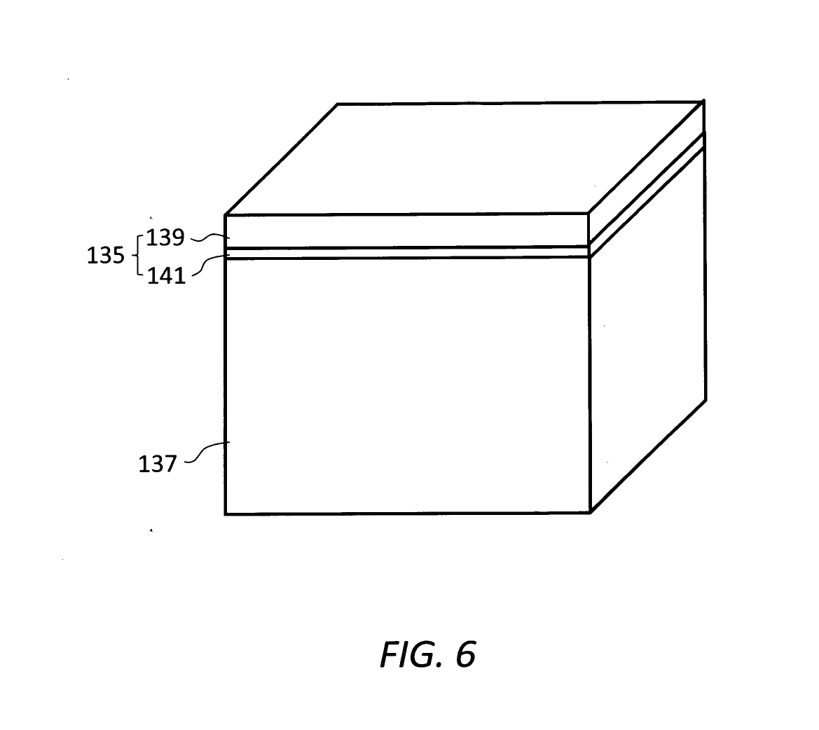

Fabrication of a trough channel transistor device will now be described with reference to FIGS. 6-14, which illustrate various intermediate structures of the transistor device. Referring to FIG. 6, the processing starts by forming a first hard mask layer 135 on a semiconductor substrate 137 upon which the transistor device is to be fabricated. The substrate 137 can be any semiconductor substrate known in the art, such as Si, SiGe, SiC, SiCGe, II-VI compounds, III-V compounds, or semiconducting epitaxial layers over such substrates. In an embodiment, the substrate 137 is made of silicon. In another embodiment, the semiconductor substrate 137 has a p-type conductivity for fabricating a n-type trough channel transistor. In yet another embodiment, the semiconductor substrate 137 has a n-type conductivity for fabricating a p-type trough channel transistor. The first hard mask layer 135 may comprise one or more layers of any suitable hard mask material, including oxides, nitrides, oxynitrides, metals, or combinations thereof, deposited by a thin film deposition method such as PVD, CVD, or ALD. In a preferred embodiment, the first hard mask layer 135 comprises a pad oxide layer 141 and a silicon nitride mask layer 139 formed thereon.

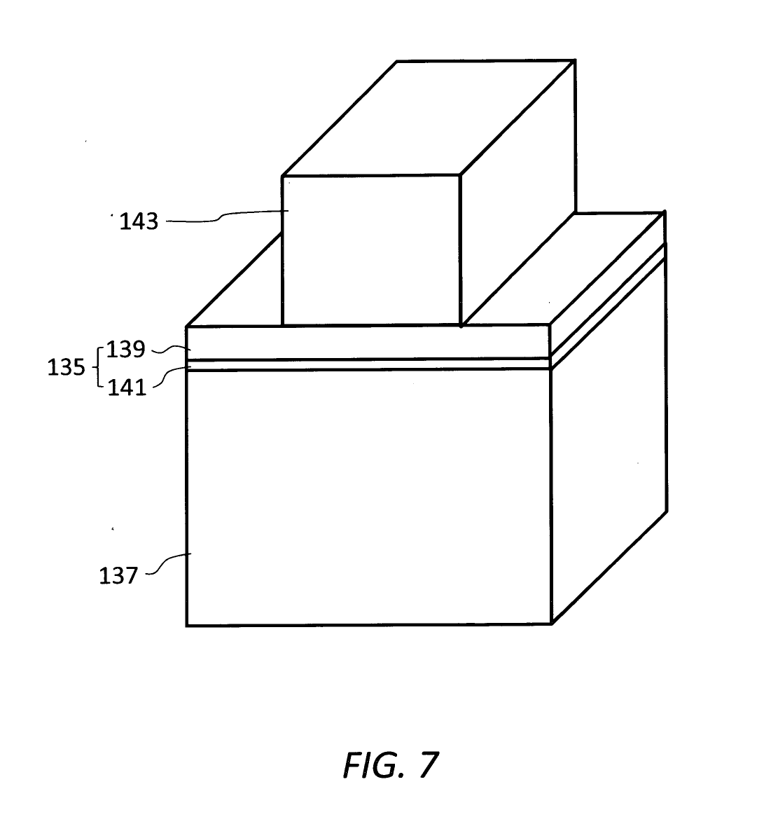

Referring to FIG. 7, the processing continues by forming a first patterned mask 143 on top of the first hard mask layer 135. In an embodiment, the first patterned mask 143 may comprise any organic resist material patterned by photo lithography, e-beam lithography, or nanoimprint lithography. In another embodiment, the first patterned mask 143 can be any inorganic material which is different from the top layer of the first mask layer 139 and which has good etch resistance, or etch selectivity, compared with the substrate 137. For example, the first patterned mask 143 can be amorphous carbon or silicon oxide patterned by lithography and etch processes. In an alternative embodiment, the first patterned mask 143 can also be formed by self-aligned spacer methods which utilize combinations of lithography, film deposition, and etch processes to pattern high resolution masks in a manner as well known to one of skill in the art (for instance, see U.S. Pat. No. 7,846,756B2 issued to Yen et alia).

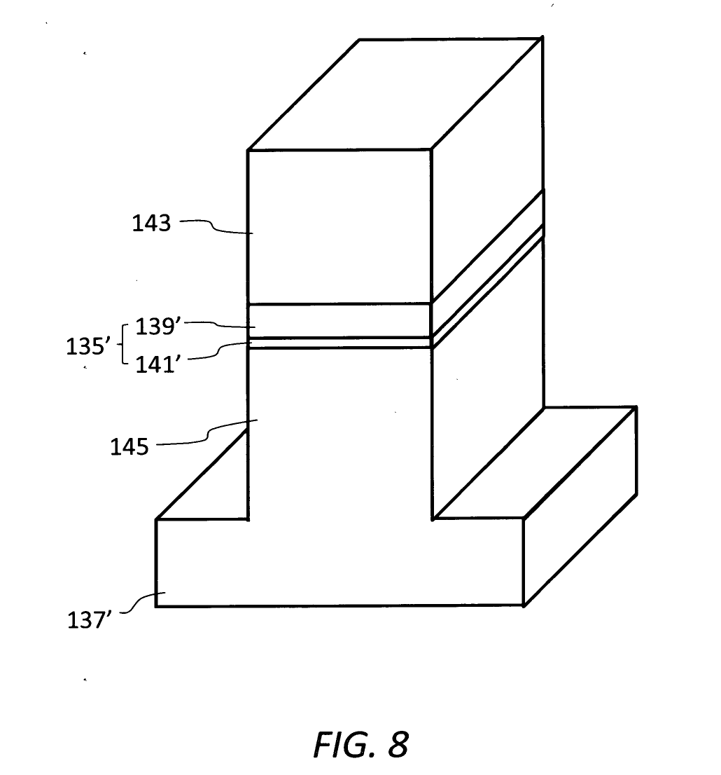

Referring to FIG. 8, the processing continues by etching through the first hard mask 135′ and into the substrate 137′ while leaving the region beneath the patterned mask 143 intact, thereby forming a mesa feature 145 on the substrate 137′. In some embodiments where the substrate 137′ is silicon, it is preferably to use a RIE process which utilizes a gas chemistry comprising hydrogen bromide (HBr) and chlorine (Cl₂).

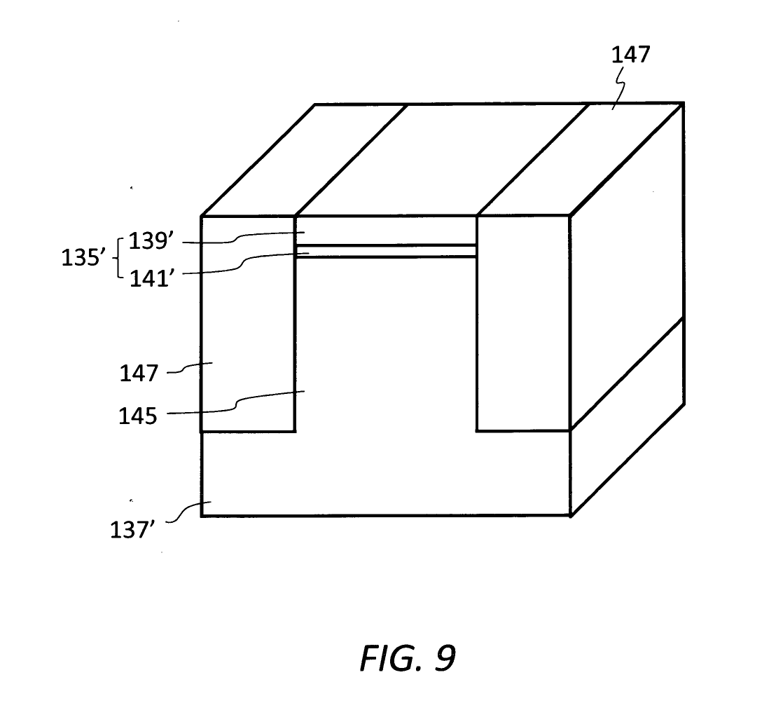

After formation of the mesa feature 145, the first patterned mask 143 is removed. A layer of isolation insulator is then blanket-deposited over the entire structure and followed by a planarization process such as CMP as illustrated in FIG. 9. The initial thickness of the as-deposited isolation insulator 147 prior to planarization preferably exceeds the combined thickness of the first hard mask 135′ and the mesa feature 145. The planarization process removes excess insulator material such that the final thickness of the isolation insulator 147 does not exceed the combined thickness of the first hard mask 135′ and the mesa feature 145. The isolation insulator 147 may comprise any insulator material which has a higher CMP removal rate compared with the first hard mask 135′. In one embodiment, the isolation insulator 147 comprises silicon oxide deposited by PVD, CVD, or ALD.

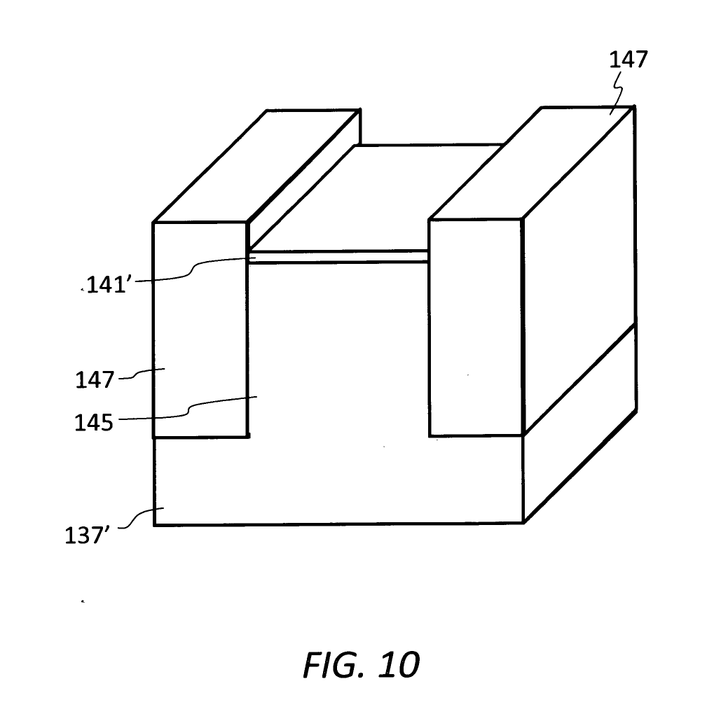

After the planarization process, the first hard mask 135′ is removed, thereby forming a notch on top. In some embodiments where the first hard mask 135′ comprises the silicon nitride mask 139′ and the pad oxide 141′, only the former is removed as illustrated in FIG. 10. The silicon nitride mask 139′ may be preferentially removed by a wet etch process using hot phosphoric acid.

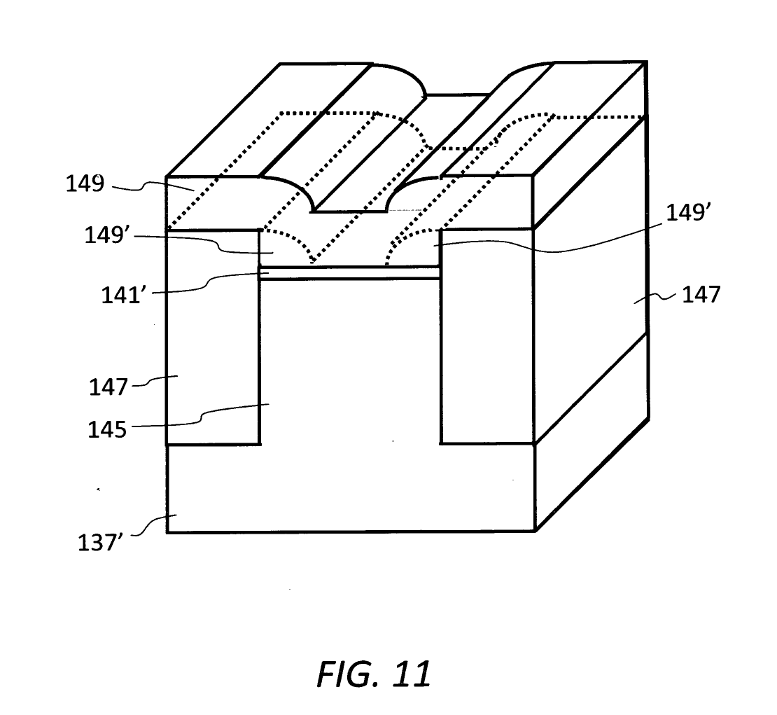

Referring to FIG. 11, a second hard mask layer 149 is formed over the notch on top by PVD, CVD, or ALD. The second hard mask layer 149 may comprise any hard mask material which has good etch selectivity with respect to the material of the mesa feature 145 therebeneath and which has good thermal stability above 1000° C., such as silicon oxide or aluminum oxide. The processing continues by vertically etching the second hard mask layer 149 to form a second hard mask 149′ (dashed lines) and to expose center top of the mesa feature 145. In an embodiment, the second hard mask layer 149 is made of silicon oxide and the vertical etching thereof may be accomplished by using a trifluoromethane (CHF₃) RIE or other oxide etch chemistries. In another embodiment where the second hard mask layer 149 is made of aluminum oxide, the vertical etching can be accomplished by using a RIE chemistry comprising boron tricholoride (BCl₃) and chlorine (Cl₂).

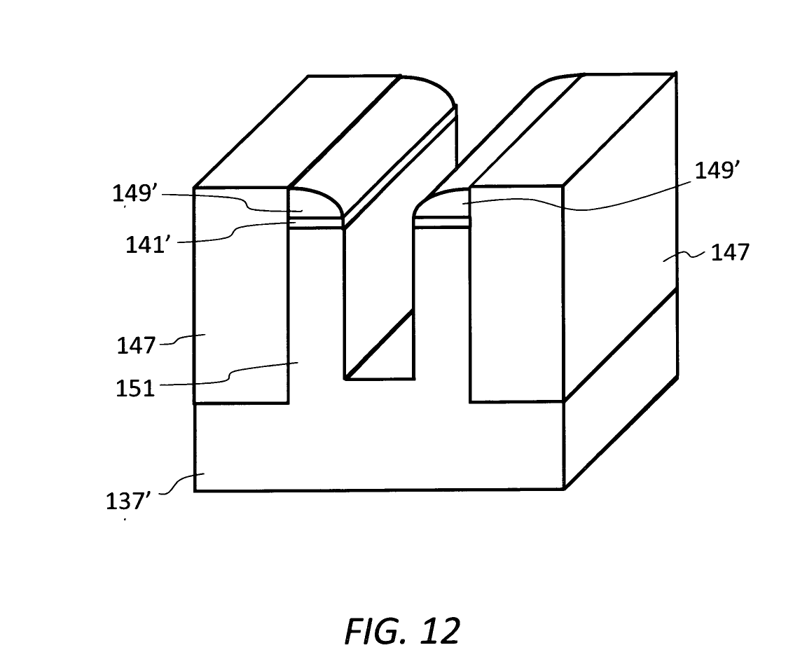

After forming the second hard mask 149′, the center region of the mesa feature 145 not protected by the second hard mask 149′ is vertically etched to a depth not exceeding the height of the mesa feature 145, resulting in a trough structure 151 protruding from the substrate 137′ illustrated in FIG. 12. In some embodiments where the substrate 137′ is made of silicon, the vertical dry etching of the mesa feature 145 may be accomplished by a RIE gas chemistry comprising HBr and Cl₂.

Following the formation of the trough structure 151 by vertical etching, the second hard mask 149′ is removed by a wet etch process to expose the top surface of the trough structure 151. In some embodiments where the pad oxide 141′ is used, the remaining pad oxide 141′ beneath the second hard mask 149′ is also removed to expose the underlying trough structure 151. As would be understood by a person of skill in the art, the process of removing the second hard mask 149′ will also remove some isolation insulator 147 on top, thereby reducing the height of the isolation insulator 147 to a level comparable to that of the trough structure 151.

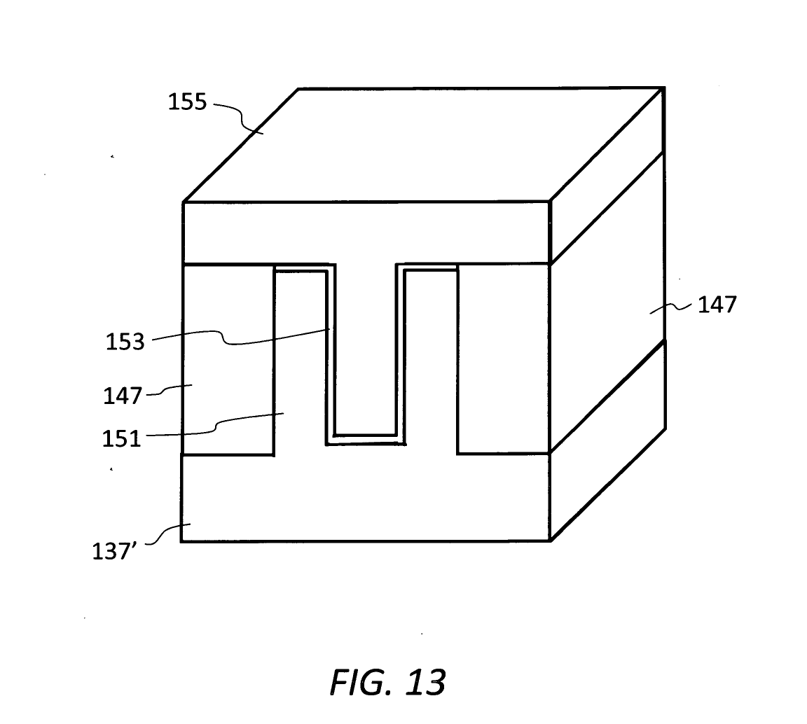

After removing the second hard mask 149′ and exposing the top surface of the trough structure 151, the surface is cleaned and a conforming gate dielectric layer 153 is formed on the top surface and inside surface of the trough structure 151 as shown in FIG. 13. The gate dielectric layer 153 can be deposited by ALD or CVD and may comprise any material with sufficiently high dielectric constant, including but not limited to SiOₓ, SiOₓN_{Y}, HfOₓ, HfOₓN_{y}, HfSiOₓ, HfSiOₓN_{y}, ZrOₓ, ZrOₓN_{y}, ZrSiOₓ, ZrSiOₓN_{y}, AlOₓ, or combinations thereof. In embodiments where the trough structure 151 is made of silicon, the gate dielectric layer 153 may be formed of silicon oxide by thermal oxidation of the top and inner surfaces of the trough structure 151.

With continuing reference to FIG. 13, after the formation of the gate dielectric layer 153, a gate electrode layer 155 is deposited and fills the trough structure 151, and then planarized by CMP. The gate electrode layer 155 may include any conductive material, such WSiₓ, CoSiₓ, NiSiₓ, TaNₓ, TiNₓ, Ta, W, or combinations thereof. In an embodiment, the gate electrode layer 155 is formed of doped polysilicon. In another embodiment, the gate electrode layer 155 is formed of TiNₓ.

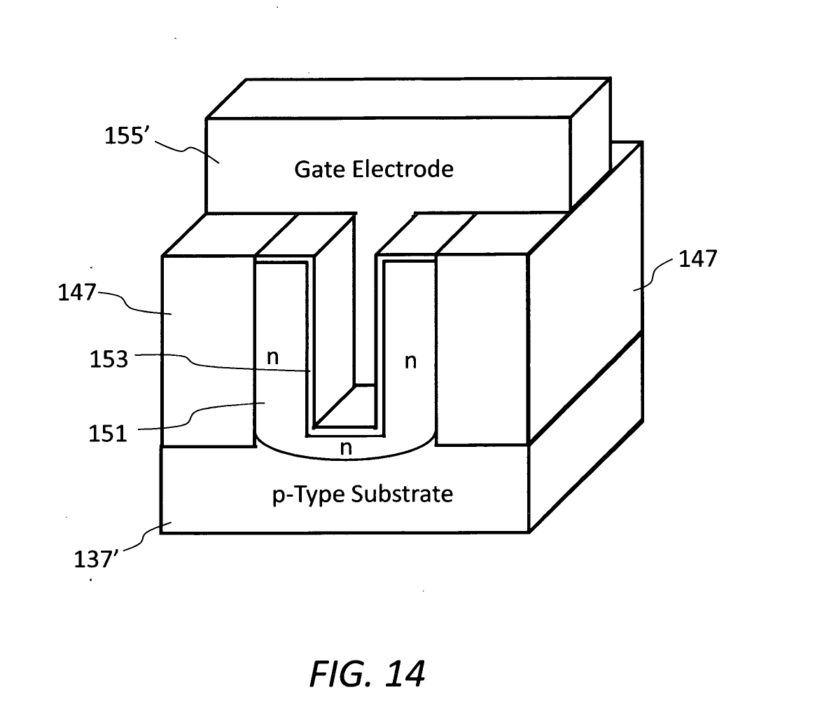

Referring to FIG. 14, a gate electrode 155′ is formed by combined processes of lithography, hard mask formation and vertical dry etch of the gate electrode layer 155 in a manner as well known to one of skill in the art. Alternatively, the patterning process may also include a self-aligned spacer step to further reduce the width of the gate electrode 155′, which determines the trough channel length. The vertical etch process for the gate electrode 155′ preferably stops at the gate dielectric layer 153 without etching therethrough.

Ion implantation of the trough structure 151 follows the formation of the gate electrode 155′ to define source and drain regions. The gate electrode 155′ serves as an implantation mask to preserve the conductivity type of the region of the trough structure 151 beneath the electrode 155′. In regions of the trough structure not protected by the electrode 155′, dopant is implanted into the trough wall and bottom by angled ion implantation in such a way that these regions have a different conductivity type compared with the substrate 137′ and the trough region beneath the electrode 155′. The two implanted regions of the trough structure separated by the gate electrode 155′ respectively form source and drain regions. In some embodiments where a n-type trough channel transistor is fabricated, implanted dopant may comprise any Group III element, including boron, aluminum, indium, or gallium. In alternative embodiments where a p-type trough channel transistor is fabricated, implanted dopant may comprise any Group V element, such as phosphorous, arsenic, or antimony. After ion implantation to define source and drain regions, the processing of the trough channel transistor follows that of conventional MOSFET in a manner as well known to one of skill in the art.

While the present invention has been shown and described with reference to certain preferred embodiments, it is to be understood that those skilled in the art will no doubt devise certain alterations and modifications thereto which nevertheless include the true spirit and scope of the present invention. Thus the scope of the invention should be determined by the appended claims and their legal equivalents, rather than by examples given.

1. A trough channel transistor device comprising:
a semiconductor substrate of a first conductivity type having a top surface;
a semiconductor trough structure protruding from the top surface of said substrate and having a central trough extending along a first direction and having first and second top surfaces disposed adjacent to the central trough, two outer lateral surfaces, and an inner central trough surface;
a layer of isolation insulator disposed on said substrate and abutting the outer lateral surfaces of said semiconductor trough structure;
a gate dielectric layer lining the inner central trough surface and the top surfaces of said semiconductor trough structure; and
a gate electrode disposed on top of said isolation insulator and extending over and into a selected gate electrode area of said central trough with said gate dielectric layer interposed therebetween,
wherein said semiconductor trough structure under the selected gate electrode area has the first conductivity type and first and second regions of the semiconductor trough structure adjacent to opposite sides of selected gate electrode area and not directly beneath said gate electrode have a second conductivity type opposite to the first conductivity type provided in said semiconductor substrate.

2. The trough channel transistor device according to claim 1, wherein the first conductivity is p type and the second conductivity is n type.

3. The trough channel transistor device according to claim 1, wherein the first conductivity is n type and the second conductivity is p type.

4. The trough channel transistor device according to claim 1, wherein said semiconductor substrate comprises silicon.

5. The trough channel transistor device according to claim 1, wherein said gate dielectric layer comprises silicon oxide.

6. The trough channel transistor device according to claim 1, wherein said gate dielectric layer is formed of a compound comprising hafnium and oxygen.

7. The trough channel transistor device according to claim 1, wherein said isolation insulator is formed of silicon oxide, silicon nitride or silicon oxynitride.

8. The trough channel transistor device according to claim 1, wherein said gate electrode comprises doped polysilicon.

9. The trough channel transistor device according to claim 1, wherein said gate electrode comprises at least one layer formed of titanium nitride.

10. The trough channel transistor device according to claim 1, wherein said central trough has a rectangular cross section.

11. The trough channel transistor device according to claim 1, wherein said central trough has a semi-circular or a semi-elliptical cross section.

12. The trough channel transistor device according to claim 1, wherein said central trough has a triangular or a trapezoidal cross section.

13. The trough channel transistor device according to claim 1, wherein the depth of said central trough is less than the height of said semiconductor trough structure.

14. The trough channel transistor device according to claim 1, wherein the first and second regions of the semiconductor trough structure adjacent to opposite sides of selected gate electrode area of said semiconductor trough structure not directly beneath said gate electrode respectively define source and drain regions.

15. A trough channel transistor device comprising:
a silicon substrate of a first conductivity type having a top surface;
a silicon trough structure protruding from the top surface of said substrate and having a central trough oriented along a first direction and having two top surfaces, two outer lateral surfaces, and an inner central trough surface;
a layer of silicon oxide isolation insulator disposed on said silicon substrate and abutting the outer lateral surfaces of said silicon trough structure;
a silicon oxide gate dielectric layer lining the inner central trough surface and the top surfaces of said silicon trough structure; and
a doped polysilicon gate electrode disposed in a selected gate electrode area of the central trough on top of said silicon oxide isolation insulator and extending over and filling said selected gate electrode area of the central trough,
wherein said doped polysilicon gate electrode extends along a second direction not parallel to the first direction of said central trough, first and second regions of said silicon trough structure disposed on opposite sides of selected gate electrode area of the central trough not directly beneath said doped polysilicon gate electrode have a second conductivity type opposite to the first conductivity type provided in said substrate.

16. The trough channel transistor device according to claim 15, wherein the first conductivity is p type and the second conductivity is n type.

17. The trough channel transistor device according to claim 15, wherein the first conductivity is n type and the second conductivity is p type.

18. A method for fabricating a trough channel transistor comprising the steps of:
providing a semiconductor substrate having a first type of conductivity;
forming a mesa feature having a first hardmask thereover on said substrate;
forming a layer of isolation insulator on top of said substrate and adjacent to said mesa feature;
removing said first hardmask on said mesa feature to form a notch between the top surfaces of said mesa feature and said isolation insulator;
forming a second hardmask aligned to said notch on said mesa feature;
forming a trough structure having two top surfaces, two outer lateral surfaces, and an inner surface by selectively etching said mesa feature with said second hardmask thereover;
forming a gate dielectric layer over the top surfaces and the inner surface of said trough structure;
forming a gate electrode filling said trough structure with said gate dielectric layer interposed therebetween; and
implanting said trough structure with a dopant of a second type of conductivity, opposite to the first type provided by said substrate, using said gate electrode as a mask to define source and drain regions.

19. The method according to claim 18, wherein said first hardmask comprises a pad oxide layer and a silicon nitride mask layer formed thereover.

20. The method according to claim 18, wherein said second hardmask is formed of silicon oxide or aluminum oxide.

21. The method according to claim 18, wherein said semiconductor substrate is formed of silicon and said gate dielectric layer is formed of silicon oxide.

22. The method according to claim 21, wherein the step of forming said gate dielectric layer over the top surfaces and the inner surface of said trough structure is carried out by thermal oxidation of said trough structure.
